(19) United States
(12) Patent Application Publication
(10) Pub. No.: US 2020/0378540 A1
(43) Pub. Date: Dec. 3, 2020

(54) THERMAL MANAGEMENT METHOD AND APPARATUS

(71) Applicant: Edwards Limited, Burgess Hill, Sussex (GB)

(72) Inventor: Laurent Marc Philippe, Burgess Hill, Sussex (GB)

(21) Appl. No.: 16/769,688

(22) PCT Filed: Dec. 4, 2018
(86) PCT No.: PCT/GB2018/053506

§ 371 Date: Jun. 4, 2020

(30) Foreign Application Priority Data
Dec. 5, 2017 (GB) 1720231.8

(51) Int. Cl. F16L 53/37; C23C 16/44; H05B 3/42

(52) U.S. Cl. CPC F16L 53/37; H05B 2203/022; H05B 3/42; C23C 16/4412

(57) ABSTRACT

The present disclosure relates to a thermal management system (2) configured to heat a conduit (4) composed of metal. The thermal management system (2) includes an electrical generator (16) for generating alternating current at a high frequency. First and second electrical connectors (19, 20) are provided for connecting the electrical generator (16) to the conduit (4). In use, the electrical generator (16) outputs alternating current at a high frequency to the first and second electrical connectors (19, 20), the alternating current being introduced into the conduit (4) and causing direct heating of the conduit (4). The present disclosure also relates to an exhaust system (1) comprising a comprising a thermal management system (2); and to a related method of heating a conduit (4).

CROSS-REFERENCE OF RELATED APPLICATION

This application is a Section 371 National Stage Application of International Application No. PCT/GB2018/053506, filed Dec. 4, 2018, and published as WO 2019/110975 A1 on Jun. 13, 2019, the content of which is hereby incorporated by reference in its entirety and which claims priority of British Application No. 1720231.8, filed Dec. 5, 2017.

### FIELD

The present disclosure relates to a thermal management method and apparatus. In particular, but not exclusively, the present disclosure relates to a thermal management system for a conduit; an exhaust system comprising a thermal management system; and a method of heating a conduit.

### BACKGROUND

An exhaust system 101 comprising a known thermal management system (TMS) 102 is illustrated in FIG. 1. The TMS 102 is operable to control the temperature of a conduit 104 for conveying process gases for an industrial process. The exhaust system 101 may, for example, be provided to transport deposition gases and associated powders exhausted from a chemical vapour deposition (CVD) process. The TMS 102. comprises a controller 115 and a plurality of resistive heater pads 123. The controller 115 is configured to supply a current to each of the resistive heater pads 123. The resistive heater pads 123 are separate from each other and disposed along the length of the conduit 104. The resistive heater pads 123 may each be one (1) metre in length, so for a conduit 104 which is ten (10) metres in length it may be necessary to provide ten (10) of said resistive heater pads 123. If the conduit 104 has a complex geometry, for example comprising one or more bends or valves, it may be necessary to provide additional resistive heater pads 123. In use, the resistive heater pads 123 are heated and the conduit 104 is heated through thermal conduction. However, the heat transfer from the resistive heater pads 123 to the conduit 104 may be poor, especially on stainless steel which is a poor thermal conductor. The resistive heater pads 123 may be difficult to install, particularly if the conduit 104 has a complex geometry. Moreover, the heat transfer from the resistive heater pads 123 depends on the quality of the fitting onto the conduit 104 which is operator dependent. The resistive heater pads 123 may also be prone to failures and defects.

The present invention seeks to overcome or ameliorate at least some of the problems associated with prior art systems.

The discussion above is merely provided for general background information and is not intended to be used as an aid in determining the scope of the claimed subject matter. The claimed subject matter is not limited to implementations that solve any or all disadvantages noted in the background.

### SUMMARY

Aspects of the present invention relate to a thermal management system; an exhaust system comprising a thermal management system; a method of heating a conduit; and a non-transitory computer-readable medium as claimed in the appended claims.

According to an aspect of the present invention there is provided a thermal management system for heating a conduit composed of metal, the thermal management system comprising:
an electrical generator for generating alternating current at a high frequency; and
first and second electrical connectors for connecting the electrical generator to the conduit;
wherein, in use, the electrical generator outputs alternating current at a high frequency to the first and second electrical connectors, the alternating current being introduced into the conduit and causing direct heating of the conduit. In use, the alternating current is introduced directly into the conduit. The supply of alternating current causes direct heating of the conduit by Joule effect. Thus, the heat is generated in the core of the conduit. By heating the conduit itself (rather than a resistive heater pad positioned against its outer surface), heat transfer may be improved. By supplying the alternating current at a high frequency, the effective resistance of the conductor is increased. As a result, there may be greater power dissipation (also called I2R loss) into the conduit which, at least in certain embodiments, may cause increased heating compared to prior art systems. At least in certain embodiments, the magnitude of the alternating current is lower than the direct current required to provide equivalent heating.

The same current flows through the conduit between the connections established by said first and second connectors. Thus, the temperature may be at least substantially uniform along that length of the conduit. A single temperature measurement (for example by a Thermocouple or other temperature sensor) located somewhere along the conduit may be sufficient to monitor the temperature within that section. The first electrical connector may be connected at or proximal to a first end of the conduit; and the second electrical connector may be connected at or proximal to a second end of the conduit. In this arrangement, the conduit may be heated along its length.

The thermal management system may be used to provide heating of conduits having complex shapes, for example comprising check valves, bends, etc. The need to provide separate resistive heater pads is reduced or removed.

The electrical generator may comprise an electrical control unit (ECU) for controlling the frequency and/or magnitude at which the alternating current is generated. The ECU may comprise one or more processors.

At least in certain embodiments, the alternating current introduced into the conduit has a frequency sufficiently high to cause the current to flow predominantly in an outer region of the conductor, typically referred to as a “skin” of the conductor. The skin may have a depth which is equal to or less than the thickness of the conductor. The term “high frequency” used herein may be understood as referring to a frequency greater than or equal to 100 Hertz.

The electrical generator may be configured to output alternating current at a frequency greater than or equal to 100 Hertz (Hz).

The electrical generator may be configured to output alternating current at a frequency greater than or equal to 1 kilohertz (kHz).

The electrical generator may be configured to output alternating current at a frequency greater than or equal to 10 kilohertz (kHz).

The electrical generator may be configured to output alternating current at a frequency greater than or equal to 50 kilohertz (kHz).

The electrical generator may be configured to output alternating current at a frequency greater than or equal to 100 kilohertz (kHz).

The electrical generator may be configured to output alternating current at a frequency less than or equal to 500 kilohertz (kHz). In certain embodiments, the electrical generator may be configured to output alternating current at a frequency greater than 500 kilohertz (kHz).

The electrical generator may be re-configurable to output alternating current at different frequencies.

The electrical generator may be configured to output alternating current having a magnitude less than or equal to one of the following: 50 Amps or 20 Amps.

In use, the voltage in the conduit may be less than or equal to 60 Volts; or less than or equal to 48V.

The first and second electrical connectors may each comprise a cable comprising multiple strands of individually insulated wire. The first and second electrical connectors may, for example, each comprise a Litz wire.

At least in certain embodiments, monitoring the current intensity flowing through the conduit will indicate whether a fault is present or not. The presence of a current flowing through the conduit ensures continuity and therefore assures that the conduit is well heated.

The thermal management system may comprise a fault detection module. The fault detection module may be configured to identify when the electrical resistance exceeds a predetermined threshold, or is outside a predetermined operating range. The fault detection module may calculate the electrical resistance in dependence on the current and voltage output by the electrical generator. If the electrical resistance exceeds a predetermined threshold, the fault detection module may determine that there is a poor or faulty electrical connection, for example between subsections of the conduit and/or between the first and second electrical connectors and the conduit. The fault detection module may operate continuously. Alternatively, the fault detection module may operate periodically, for example in a fault detection mode.

The first electrical connector may be connected to the conduit at or proximal to an inlet of the conduit. The second electrical connector may be connected to the conduit at or proximal to an outlet of the conduit.

The first and second electrical connectors may be configured to be connected to first and second electrical points provided on the conduit. The electrical points may be fastened to the conduit, for example by a mechanical fastener. The electrical points may be permanently attached to the conduit, for example by welding.

The conduit may be an exhaust conduit. The exhaust conduit may be suitable for conveying process gases, for example from a chemical vapour deposition (CVD) process. The exhaust conduit may form part of an exhaust system, for example in an industrial process.

Alternatively, the conduit may be a foreline. The conduit may be configured to supply gases for an industrial process.

Alternatively, or in addition, the thermal management system may be suitable for heating a valve. The valve may, for example, be connected to a conduit. The thermal management system may be suitable for heating both the conduit and the valve. By way of example, the thermal management system may be suitable for heating an isolation valve present on either an exhaust conduit or a foreline.

According to a further aspect of the present invention there is provided an exhaust system comprising a thermal management system as described herein and at least one conduit, the first and second electrical connectors being connected to said at least one conduit.

The exhaust system may optionally comprise at least one valve, such as an isolation valve. In use, the thermal management system may heat the at least conduit and the at least one valve.

The at least one conduit may be electrically isolated. The at least one conduit may be supported by one or more supports each comprising an electrical insulator for electrically isolating the conduit. The electrical insulator may comprise an electrically insulating coating, such as a Teflon™ coating. Alternatively, or in addition, the electrical insulator may comprise an electrically insulating member for contacting the conduit. Alternatively, or in addition, each support may be composed of an electrically insulating material.

The exhaust system may comprise first and second couplings disposed at respective ends of the at least one conduit. The first and second couplings may be arranged to form a fluid-tight seal, for example to seal an inlet and an outlet of the conduit. The first and second couplings may each comprise an O-ring, for example composed of an elastomeric material or rubber. The first and second couplings may each comprise an electrically insulating coupling. Thus, the first and the second couplings may be suitable for electrically isolating the conduit.

The exhaust system may comprise a thermal insulator for thermally insulating the conduit. For example, the exhaust system may comprise lagging disposed around the conduit.

The at least one conduit may be composed of stainless steel. The at least one conduit may be composed of other metals, for example having a higher resistivity.

The at least one conduit may be composed of a magnetic material. For example, the at least one conduit may comprise magnetised stainless steel. The at least one conduit may be composed of a magnetic material having a relative magnetic permeability greater than one (>1). By forming the at least one conduit from a magnetic material, effective electrical resistivity of the material will be increased, thereby promoting thermal heating. The at least one conduit may be composed of a ferromagnetic material.

According to a further aspect of the present invention, there is provided a method of heating a conduit composed of metal, the method comprising:

using an electrical generator to introduce alternating current to the conduit, the alternating current being introduced directly into the conduit at a high frequency to heat the conduit by Joule effect.

The alternating current may be at a frequency greater than or equal to 100 Hertz (Hz).

The alternating current may be at a frequency greater than or equal to 1 kilohertz (kHz).

The alternating current may be at a frequency greater than or equal to 10 kilohertz (kHz).

The alternating current may be at a frequency greater than or equal to 50 kilohertz (kHz).

The alternating current may be at a frequency greater than or equal to 100 kilohertz kHz).

The alternating current may be at a frequency less than or equal to 500 kilohertz (kHz). In certain embodiments, the alternating current may be at a frequency greater than 500 kilohertz (kHz).

The alternating current may have a magnitude less than or equal to one of the following; 50 Amps or 20 Amps.

The voltage in the conduit is less than or equal to 60 Volts, or less than or equal to 48 Volts.

The method may comprise modifying the frequency of the alternating current in dependence on one or more parameters of the conduit. For example, the frequency of the alternating current may be modified in dependence on one or more of the following parameters: a length of the conduit; a diameter of the conduit; a wall thickness of the conduit; a conductivity of the material forming the conduit; and a material from which the conduit is formed.

The method may comprise monitoring an electrical resistance of the conduit to detect a fault. The method may comprise detecting a fault when the electrical resistance exceeds a predetermined threshold or is outside a predetermined operating range. The electrical resistance may be calculated in dependence on the current and voltage output to the conduit. If the electrical resistance exceeds a predetermined threshold, the fault detection module may determine that there is a poor or faulty electrical connection, for example between subsections of the conduit and/or between the conduit and one or more electrical connectors. The method may comprise monitoring the electrical resistance continuously. Alternatively, the method may comprise monitoring the electrical resistance periodically, for example in a fault detection mode

According to a further aspect of the present invention there is provided a non-transitory computer-readable medium having a set of instructions stored therein which, when executed, cause a processor to perform the method described herein.

Any control unit or controller described herein may suitably comprise a computational device having one or more electronic processors. The system may comprise a single control unit or electronic controller or alternatively different functions of the controller may be embodied in, or hosted in, different control units or controllers. As used herein the term “controller” or “control unit” will be understood to include both a single control unit or controller and a plurality of control units or controllers collectively operating to provide any stated control functionality. To configure a controller or control unit, a suitable set of instructions may be provided which, when executed, cause said control unit or computational device to implement the control techniques specified herein. The set of instructions may suitably be embedded in said one or more electronic processors. Alternatively, the set of instructions may be provided as software saved on one or more memory associated with said controller to be executed on said computational device. The control unit or controller may be implemented in software run on one or more processors. One or more other control unit or controller may be implemented in software run on one or more processors, optionally the same one or more processors as the first controller. Other suitable arrangements may also be used.

Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible. The applicant reserves the right to change any originally filed claim or file any new claim accordingly, including the right to amend any originally filed claim to depend from and/or incorporate any feature of any other claim although not originally claimed in that manner.

The Summary is provided to introduce a selection of concepts in a simplified form that are further described in the Detail Description. This summary is not intended to identify key features or essential features of the claimed subject matter, nor is it intended to be used as an aid in determining the scope of the claimed subject matter.

### BRIEF DESCRIPTION OF THE DRAWINGS

One or more embodiments of the present invention will now be described, by way of example only, with reference to the accompanying figures, in which:

FIG. 1 shows a schematic representation of a prior art thermal management system for an exhaust system;

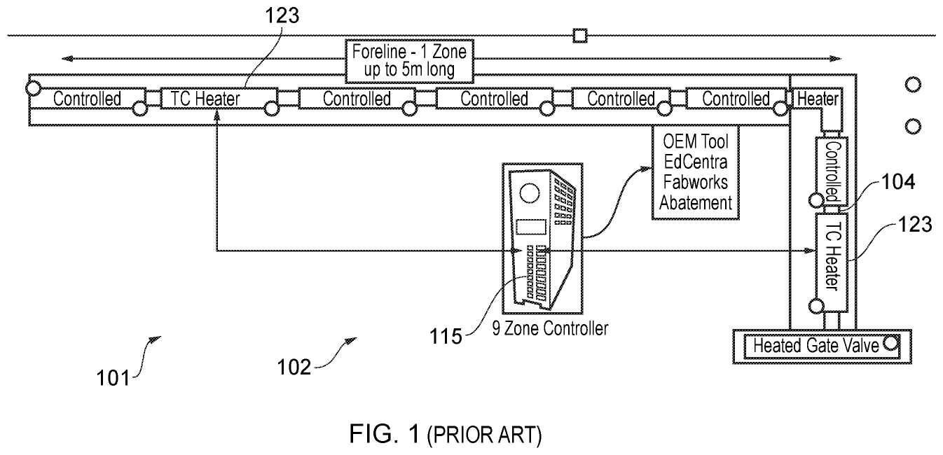

FIG. 2 shows a schematic representation of a thermal management system in accordance with an embodiment of the present invention; and

FIG. 3 is a graph showing the relationship between electrical current and frequency to dissipate a fixed amount of power for a given section of conduit.

### DETAILED DESCRIPTION

An exhaust system 1 comprising a thermal management system (TMS) 2 in accordance with an embodiment of the present invention will now be described with reference to the accompanying figures. The exhaust system 1 is suitable for conveying process gases comprising condensable solids to an abatement device 3 connected to the exhaust system 1. The exhaust system 1 may, for example, be provided to transport deposition gases and associated powders expelled from a chemical vapour deposition (CVD) process. The TMS 2 is configured to control the temperature of the exhaust system 1 to ensure that compounds remain volatile, thereby preventing or suppressing the accumulation of solids which may partially or completely block the exhaust system 2. It will be understood that the TMS 2 and the exhaust system 1 may be utilised in other industrial processes.

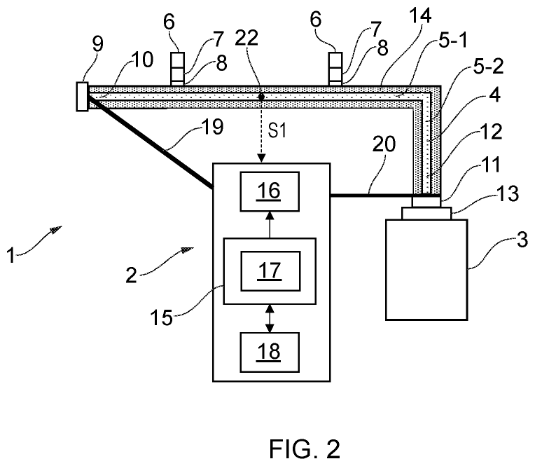

As shown in FIG. 2, the exhaust system 1 comprises a conduit 4. The conduit 4 is in the form of a tube composed of a metal, such as stainless steel. The conduit 4 may, for example, comprise a DN40 pipe having an internal diameter of 40 mm The conduit 4 may have a wall thickness of approximately 1 mm, or up to 2 mm in certain embodiments. The conduit 4 may, for example, be 10 metres or more in length and may follow a convoluted path. The conduit 4 forms a substantially continuous fluid path for conveying exhaust gases to the abatement device 3. The conduit 4 could consist of a single length of pipe. However, the conduit 4 or typically comprises a plurality of subsections 5-1, 5-2 joined together in a fluid-tight manner. The conduit 4 may comprise one or more bends to provide the required connection to the abatement device 3. The conduit 4 is supported along its length by a plurality of supports 6. The supports 6 in the present embodiment are configured to electrically isolate the conduit 4. The supports 6 in the present embodiment each comprise a clamp 7 having an electrically insulating coating 8, such as Teflon™, for contacting an exterior surface of the conduit 4. In a variant, an electrically insulating insert (not shown) may be provided between the clamp 7 and the conduit 4. In a variant, the supports 6 may be formed of an electrically insulating material.

An inlet coupling 9 is provided at an inlet 10 of the exhaust system 1; and an outlet coupling 11 is provided at an outlet 12 of the exhaust system 1. The outlet coupling 11 is provided to connect the exhaust system 1 to the abatement device 3 in the present embodiment. The inlet and outlet couplings 9, 11 each comprise an O-ring for forming a fluid-tight seal with the associated components. Furthermore, the inlet and outlet couplings 9, 11 in accordance with an aspect of the present invention are electrical insulators. The inlet and outlet couplings 9, 11 may be formed of a suitable electrically insulating material may comprise an electrically insulating member.

A gate valve 13 is provided at the outlet 12 of the exhaust system 1. The gate valve 13 is operable to selectively open and close the outlet 12. The gate valve 13 may be heated to reduce the build-up of solids. A lagging 14 is provided around an exterior of the conduit 4 in order to thermally insulate the conduit 4.

The TMS 2 comprises an electronic control unit (ECU) 15; and an electrical generator 16. The ECU 15 comprises at least one processor 17 configured to control operation of the electrical generator 16. A human machine interface (HMI) 18 is provided to control operation of the TMS 2. The electrical generator 16 and is for generating alternating current (AC) at a high frequency. As described herein, the electrical generator 16 may be configured to generate AC at a frequency greater than or equal to or equal to 100 Hertz. The TMS 2 comprises first and second electrical connectors 19, 20 for connecting the electrical generator 16 to the conduit 4. The first electrical connector 19 is connected at or proximal to the inlet 10 of the exhaust system 1; and the second electrical connector 20 is connected at or proximal to the outlet 12 of the exhaust system 1. The first and second electrical connectors 19, 20 in the present embodiment each comprise a cable comprising multiple strands of individually insulated wire which may be twisted or woven together (for example a Litz wire).

In use, the electrical generator 16 injects a high frequency electrical current into the conduit 4 via the first and second electrical connector 19, 20, The introduction of an alternating current into the conduit 4 causes heating due to Joule effect. When AC is supplied to the conduit 4, the current density is largest near the surface of the conductor since the current flows mainly in the “skin” of the conductor. Thus, heating may be more pronounced at or near the surface due to the increased current density. This is due to the so-called “skin effect” whereby the electric current flows mainly at the “skin” of a conductor. The “skin depth” (δ) is determined by the following equation:

$$δ = \sqrt{\frac{2 ρ}{ωμ}} .$$

Where: δ=skin depth,
ρ=resistivity,
ω=angular speed, and
μ=magnetic permeability.

The skin depth decreases as the frequency of the AC increases. The effective resistance of the conductor increases with higher frequencies due to the reduction in the skin depth (which reduces the effective cross-section of the conductor). Thus, heating of the conduit 4 may be increased by increasing the frequency of the AC introduced by the electrical generator 16. At least in certain embodiments, introducing AC at a frequency greater than or equal to or equal to 100 Hz provides adequate heating of the conduit 4. However, the electrical generator 16 may be configured to generate AC at a higher frequency, for example to reduce the magnitude (amplitude) of the current.

The TMS 2 in accordance with an aspect of the present invention generates heat directly inside the conduit 4. Thus, the TMS 2 uses the conduit 4 as a heating element, rather than performing indirect heating using an external heating element. The operation of the TMS 2 will now be described. The power dissipated is proportional to the square of the current applied to a resistance. This relationship is defined by the following equation:

P=I²R

### Where: P =Power (Watts),

I=Current (Amps), and
R=Resistance (Ω).

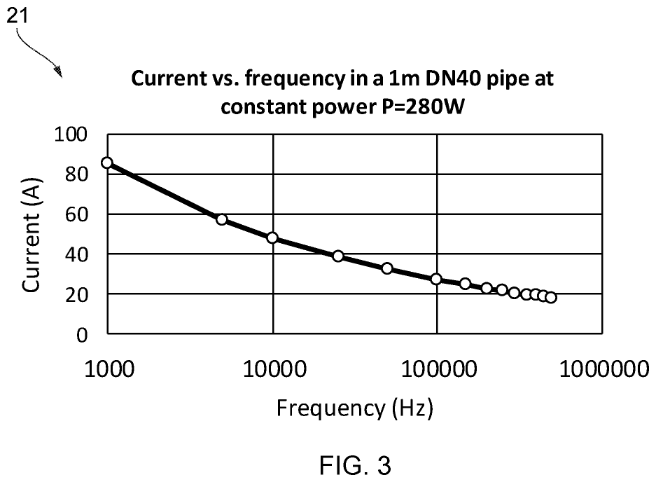

The relationship between the current and the frequency to dissipate a power of 280 Watts in a DN40 pipe of length one (1) metre is represented in a graph 21 shown in FIG. 3. The graph 21 shows that increasing the frequency of the AC allows a reduction in the magnitude of the current necessary to achieve the same power dissipation. By way of example, considering a supply frequency of 500 kHz, a current of only 18 A is needed (compared to an equivalent of 300 A in DC). Furthermore, the current injection involves low voltages (less than 48V) across the pipe length which improves safety. The electrical generator 16 may optionally also provide double insulation by implementing a small HF transformer in order to make the TMS 2 compliant to SEMI and EN61010.

By way of comparison, it will be appreciated that equivalent heating by supplying a direct current (DC) to the conduit 4 is not practical as a very high current would have to be used. A conventional DN40 conduit formed from stainless steel has a typical resistance of 2.7 milliohms/m. Considering a power density of 0.2 W/cm² along that conduit (4) (equivalent to 280W for a pipe DN40 1 metre in length, as per the example illustrated in FIG. 3), a current in excess of 300 Amps would have to be supplied. The required current could be reduced by forming the conduit (4) from a metal having a higher resistivity, but this would likely incur higher costs, and may present additional challenges, such as chemical compatibility with the compounds in the process gases.

The TMS 2 may optionally comprise one or more temperature sensor 22. Since a substantially uniform temperature is generated along the conduit 4, in certain embodiments the TMS 2 may consist of a single temperature sensor 22. The temperature sensor 22 may output a temperature signal S1 to the ECU 15 to provide feedback. The ECU 15 may thereby control the current supplied to the conduit 4 by the electrical generator 16 to maintain the conduit 4 at a desired operating temperature or within a desired temperature range.

The TMS 2 in accordance with a further aspect of the present invention may be configured to implement a fault detection mode. In particular, the TMS 2 may be configured. to check the integrity of the electrical circuit comprising the conduit 4. A predetermined voltage (V) may be applied and the current (I) measured. The resistance (R) of the conduit 4 may be calculated to determine if there is a poor electrical connection, for example between subsections of the conduit 4 or between the conduit 4 and the first and second electrical connectors 19, 20 respectively. If the resistance (R) is greater than or equal to a predetermined threshold or outside of a predetermined operating range, the TMS 2 may indicate a fault condition.

At least in certain embodiments, the TMS 2 described herein may provide efficient heating of the conduit 4 over its lifetime. The TMS one has particular application in an integrated system as access to the conduit 4 is no longer required to replace the TMS 2. The TMS 2 in certain embodiments may be considered as maintenance free.

The TMS 2 has been described herein with particular reference to an exhaust system 1. However, it will be understood that the TMS 2 may be used in other applications where heating of a conduit is required. For example, the TMS 2 may be used to provide controlled heating of a foreline or of a valve, such as an isolation valve.

It will be understood that various changes and modifications may be made to the TMS 2 described herein without departing from the scope of the present invention. For example, the conduit 4 may be made of a magnetic material. By using a magnetic material (having a relative magnetic permeability >1) for the conduit 4, the skin effect may be amplified, thereby increasing the effective resistance of the conduit 4 and promoting heating.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

1. A thermal management system for heating a conduit composed of metal, the thermal management system comprising:
an electrical generator for generating alternating current at a high frequency; and
first and second electrical connectors for connecting the electrical generator to the conduit;
wherein, in use, the electrical generator outputs alternating current at a high frequency to the first and second electrical connectors, the alternating current being introduced into the conduit and causing direct heating of the conduit.

2. The thermal management system as claimed in claim 1, wherein the electrical generator is configured to output alternating current at a frequency greater than or equal to 100 Hertz (Hz).

3. The thermal management system as claimed in claim 1, wherein the electrical generator is configured to output alternating current at a frequency greater than or equal to 1 kilohertz (kHz).

4. The thermal management system as claimed in claim 1, wherein the electrical generator is configured to output alternating current at a frequency greater than or equal to 10 kilohertz (kHz).

5. The thermal management system as claimed in claim 1, wherein the electrical generator is configured to output alternating current at a frequency greater than or equal to 100 kilohertz (kHz).

6. The thermal management system as claimed in claim 1, wherein the electrical generator is re-configurable to output alternating current at different frequencies.

7. The thermal management system as claimed in claim 1, wherein the electrical generator is configured to output alternating current having a magnitude less than or equal to one of the following: 50 Amps or 20 Amps.

8. The thermal management system as claimed in claim 1, wherein, in use, the voltage in the conduit is less than or equal to 60 Volts; or less than or equal to 48 Volts.

9. The thermal management system as claimed in claim 1, wherein the first and second electrical connectors each comprise a cable comprising multiple strands of individually insulated wire.

10. The thermal management system as claimed in claim 1 comprising a fault detection module for identifying when the electrical resistance exceeds a predetermined threshold, or is outside a predetermined operating range.

11. An exhaust system comprising a thermal management system as claimed in claim 1 and at least one conduit, the first and second electrical connectors being connected to said at least one conduit.

12. The exhaust system as claimed in claim 11, wherein the at least one conduit is electrically isolated.

13. An The exhaust system as claimed in claim 12, wherein the at least one conduit is supported by one or more supports each comprising an electrical insulator for electrically isolating the conduit.

14. The exhaust system as claimed in claim 11 comprising first and second couplings disposed at respective ends of the at least one conduit, the first and second couplings each comprising an electrically insulating coupling.

15. The exhaust system as claimed in claim 11, wherein the at least one conduit is composed of stainless steel.

16. The exhaust system as claimed in claim 11, wherein the at least one conduit is composed of a magnetic material.

17. A method of heating a conduit composed of metal, the method comprising:
using an electrical generator to introduce alternating current to the conduit, the alternating current being introduced directly into the conduit at a high frequency to heat the conduit by Joule effect.

18. The method as claimed in claim 17, wherein the alternating current is at a frequency greater than or equal to 100 Hertz (Hz).

19. The method as claimed in claim 17, wherein the alternating current is at a frequency greater than or equal to 1 kilohertz (kHz).

20. The method as claimed in claim 17, wherein the alternating current is at a frequency greater than or equal to 10 kilohertz (kHz).

21. The method as claimed in claim 17, wherein the alternating current is at a frequency greater than or equal to 100 kilohertz (kHz).

22. The method as claimed in claim 17, wherein the alternating current has a magnitude less than or equal to one of the following: 50 Amps or 20 Amps.

23. The method as claimed in claim 17, wherein the voltage in the conduit is less than or equal to 60 Volts; or less than or equal to 48 Volts.

24. The method as claimed in claim 17, comprising modifying the frequency of the alternating current in dependence on one or more parameters of the conduit.

25. The method as claimed claim 17 comprising monitoring the electrical resistance of the conduit to detect a fault.

26. The method as claimed in claim 25 comprising detecting a fault when the electrical resistance exceeds a predetermined threshold or is outside a predetermined operating range.

27. A non-transitory computer-readable medium having a set of instructions stored therein which, when executed, cause a processor to perform the method claimed in claim 19.
